(19) United States
(12) Patent Application Publication
(10) Pub. No.: US 2007/0141810 A1
(43) Pub. Date: Jun. 21, 2007

(54) Wafer dividing method

(75) Inventor: Masaru Nakamura, Tokyo (JP)

Correspondence Address: SMITH, GAMBRELL & RUSSELL, 1850 M STREET, N.W., SUITE 800, WASHINGTON, DC, 20036, US

(73) Assignee: Disco Corporation

(21) Appl. No.: 11/641,841

(22) Filed: Dec. 20, 2006

(30) Foreign Application Priority Data
Dec. 21, 2005 (JP) 2005-368409

(51) Int. Cl. H01L 21/00

(52) U.S. Cl. 438/460

(57) ABSTRACT

A method of dividing a wafer having devices which are composed of a laminate formed on the front surface of a substrate, along a plurality of streets for sectioning the devices, comprising: a laminate dividing step for dividing the laminate formed at the streets of the wafer along the streets; a deteriorated layer forming step for forming a deteriorated layer in the inside of the substrate along the streets by applying a laser beam of a wavelength having permeability for the substrate of the wafer to the rear surface of the wafer along the streets; and a dividing step for dividing the wafer along the streets by exerting external force to the wafer where the deteriorated layers have been formed.

### FIELD OF THE INVENTION

The present invention relates to a method of dividing a wafer having devices which are composed of a laminate formed on the front surface of a substrate, along a plurality of streets for sectioning the devices.

### DESCRIPTION OF THE PRIOR ART

As is known to people of ordinary skill in the art, a semiconductor wafer having a plurality of semiconductor chips such as IC's or LSI's which are formed in a matrix on the front surface of a semiconductor substrate such as a silicon substrate and composed of a laminate consisting of an insulating film and a functional film is manufactured in the production process of a semiconductor device. The above semiconductor chips are sectioned by dividing lines called “streets” in this semiconductor wafer, and individual semiconductor chips are manufactured by dividing the semiconductor wafer along the streets.

To improve the throughput of a semiconductor chip such as IC or LSI recently, a semiconductor wafer having semiconductor chips which are composed of a laminate consisting of a low-dielectric constant insulating film (Low-k film) made of an inorganic material such as SiOF or BSG (SiOB) or an organic material such as a polyimide-based, parylene-based polymer or the like and a functional film for forming circuits on the front surface of a semiconductor substrate such as a silicon substrate has recently been implemented.

A semiconductor wafer having a metal pattern composed of a metal film laminate called “test element group (TEG)” which is partially formed on the streets of the semiconductor wafer to test the function of each circuit through the metal pattern before it is divided has also been implemented.

Cutting along the streets of a wafer such as the above semiconductor wafer is generally carried out by using a cutting machine called “dicer”. This cutting machine comprises a chuck table for holding a wafer such as a semiconductor wafer, a cutting means for cutting the workpiece held on the chuck table, and a cutting-feed means for moving the chuck table and the cutting means relative to each other. The cutting means includes a rotary spindle, a cutting blade mounted on the spindle and a drive mechanism for rotary-driving the rotary spindle. The cutting blade comprises a disk-like base and an annular cutting-edge which is mounted on the side peripheral portion of the base and formed as thick as about 20 μm by fixing diamond abrasive grains having a diameter of about 3 μm to the base by electroforming.

Since the cutting blade has a thickness of about 20 μm, the streets for sectioning devices must have a width of about 50 μm. Therefore, when devices formed on the wafer are small in size, the area ratio of the streets becomes large, thereby reducing productivity.

Meanwhile, as a means of dividing a plate-like workpiece such as a semiconductor wafer, Japanese Patent No. 3408805 discloses a laser processing method for applying a pulse laser beam of a wavelength having permeability for the workpiece with its focal point set to the inside of the area to be divided. In the dividing method making use of this laser processing technique, the workpiece is divided by applying a pulse laser beam of an infrared range having permeability for the workpiece with its focal point set to the inside from one side of the workpiece to continuously form a deteriorated layer in the inside of the workpiece along the streets and exerting external force along the streets whose strength has been reduced by the formation of the deteriorated layers.

However, when a wafer having a low-dielectric constant insulating film (Low-k film) on the front surface or a wafer having a metal pattern composed of a metal film laminate called “test element group (TEG)” is to be divided by the above laser processing method, it cannot be divided along the streets without fail. That is, even when a pulse laser beam of an infrared range having permeability for the wafer is applied, with its focal point set to the inside, from one side of the wafer to form a deteriorated layer in the inside of the wafer along the streets and external force is exerted along the streets, the laminate such as the low-dielectric constant insulating film (Low-k film) cannot be divided without fail. Further, if the wafer is divided along the streets, a problem arises that the laminate peels off and reduces the qualities of the obtained chips.

### SUMMARY OF THE INVENTION

It is an object of the present invention to provide a wafer dividing method capable of dividing a wafer having a low-dielectric constant insulating film (Low-k film) on the front surface along predetermined streets without fail.

To attain the above object, according to the present invention, there is provided a method of dividing a wafer having devices which are composed of a laminate formed on the front surface of a substrate, along a plurality of streets for sectioning the devices, comprising:

a laminate dividing step for dividing the laminate formed at the streets of the wafer along the streets;

a deteriorated layer forming step for forming a deteriorated layer in the inside of the substrate along the streets by applying a laser beam of a wavelength having permeability for the substrate of the wafer from the rear surface of the wafer along the streets; and

a dividing step for dividing the wafer along the streets by exerting external force to the wafer where the deteriorated layers have been formed.

The above laminate dividing step is to form a laser-processed groove deeper than the thickness of the laminate by applying a laser beam of a wavelength having absorptivity for the laminate from the front surface side of the wafer along the streets formed on the wafer.

The above laminate dividing step is to form a scribed groove deeper than the thickness of the laminate by scribing along the streets formed on the wafer.

In the wafer dividing method of the present invention, after the laminate formed at the streets of the wafer is divided along the streets by carrying out the laminate dividing step and the deteriorated layer is formed in the inside of the substrate along the streets by carrying out the deteriorated layer forming step, the wafer is divided along the streets by exerting external force to the wafer where the deteriorated layers have been formed, thereby making it possible to divide the wafer along the streets without fail. Since the laminate is divided along the streets of the wafer by carrying out the laminate dividing step, when the wafer is divided along the streets, the laminate does not peel off and the qualities of the chips are not reduced by the peeling of the laminate, thereby solving the problems.

### BRIEF DESCRIPTION OF THE DRAWINGS

FIG. 1 is a perspective view of a semiconductor wafer to be divided by the wafer dividing method of the present invention;

FIG. 2 is an enlarged sectional view of the semiconductor wafer shown in FIG. 1;

FIG. 3 is a perspective view of the principal portion of a laser beam processing machine for carrying out the laminate dividing step and the deteriorated layer forming step in the wafer dividing method of the present invention;

FIGS. 4(a) and 4(b) are explanatory diagrams showing the laminate dividing step in the wafer dividing method of the present invention which is carried out by using the laser beam processing machine shown in FIG. 3;

FIG. 5 is an enlarged sectional view of the principal portion of the semiconductor wafer having a laser-processed groove formed in the street of the semiconductor wafer by the laminate dividing step shown in FIGS. 4(a) and 4(b);

FIG. 6 is a perspective view of the principal portion of an ultrasonic scribing apparatus for carrying out the laminate dividing step in the wafer dividing method of the present invention;

FIGS. 7(a) and 7(b) are explanatory diagrams showing the laminate dividing step (scribed groove forming step) which is carried out by using the ultrasonic scribing apparatus shown in FIG. 6 in the wafer dividing method of the present invention;

FIG. 8 is an explanatory diagram showing the laminate dividing step which is carried out by using the ultrasonic scribing apparatus shown in FIG. 7 in the wafer dividing method of the present invention;

FIGS. 9(a) and 9(b) are explanatory diagrams showing the deteriorated layer forming step which is carried out by using the laser beam processing machine shown in FIG. 3 in the wafer dividing method of the present invention;

FIG. 10 is an enlarged sectional view of the principal portion of the semiconductor wafer having the deteriorated layer formed therein by the deteriorated layer forming step shown in FIGS. 9(a) and 9(b);

FIG. 11 is an explanatory diagram showing that deteriorated layers are formed in the inside of the semiconductor wafer in the deteriorated layer forming step shown in FIGS. 9(a) and 9(b);

FIG. 12 is a perspective view of the semiconductor wafer which has been subjected to the laminate dividing step and the deteriorated layer forming step and is supported to an annular frame through a support tape;

FIG. 13 is a perspective view of a dividing apparatus for carrying out the dividing step in the wafer dividing method of the present invention; and

FIGS. 14(a) and 14(b) are explanatory diagrams showing the dividing step in the wafer dividing method of the present invention.

### DETAILED DESCRIPTION OF THE PREFERRED EMBODIMENTS

The wafer dividing method of the present invention will be described in more detail hereinunder with reference to the accompanying drawings.

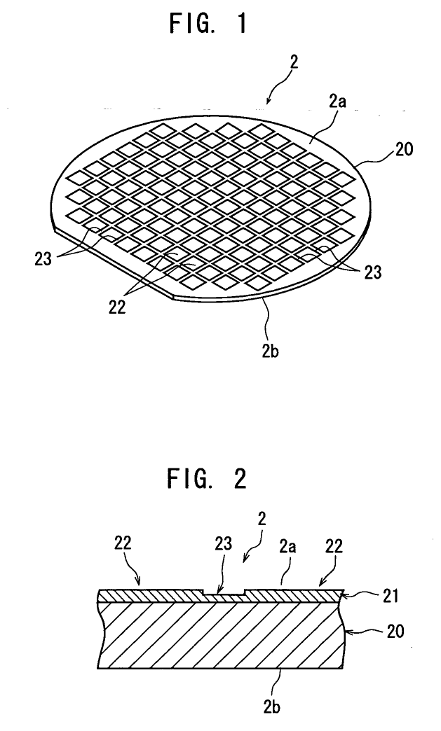

FIG. 1 is a perspective view of a semiconductor wafer to be divided into individual chips by the wafer dividing method of the present invention, and FIG. 2 is an enlarged sectional view of the principal portion of the semiconductor wafer shown in FIG. 1. In the semiconductor wafer 2 shown in FIG. 1 and FIG. 2, a plurality of devices 22 such as IC's or LSI's are formed in a matrix on the front surface of a semiconductor substrate 20 such as a silicon substrate and composed of a laminate 21 consisting of an insulating film and a functional film for forming circuits. The devices 22 are each sectioned by streets 23 formed in a lattice. In the illustrated embodiment, the insulating film for forming the laminate 21 is an SiO₂ film or a low-dielectric constant insulating film (Low-k film) made of an inorganic material such as SiOF or BSG (SiOB) or an organic material such as a polyimide-based, parylene-based polymer or the like. The rear surface of the semiconductor substrate 20 of the semiconductor wafer 2 is ground to a predetermined thickness.

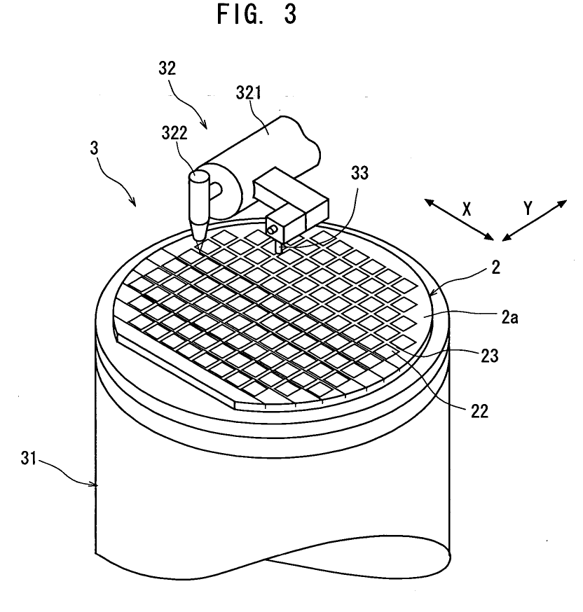

A first embodiment of the method of dividing the above semiconductor wafer 2 along the streets 23 will be described with reference to FIG. 3 to FIG. 14.

In the first embodiment, the step of dividing the laminate 21 formed at the streets 23 of the semiconductor wafer 2 along the streets 23 is first carried out. This laminate dividing step is carried out by using a laser beam processing machine 3 shown in FIG. 3. The laser beam processing machine 3 shown in FIG. 3 comprises a chuck table 31 for holding a workpiece, a laser beam application means 32 for applying a laser beam to the workpiece held on the chuck table 31, and an image pick-up means 33 for picking up an image of the workpiece held on the chuck table 31. The chuck table 31 is designed to suction-hold the workpiece and to be moved in the processing-feed direction indicated by an arrow X and the indexing-feed direction indicated by an arrow Y in FIG. 3 by a moving mechanism that is not shown.

The above laser beam application means 32 has a cylindrical casing 321 arranged substantially horizontally. In the casing 321, there is installed a pulse laser beam oscillation means (not shown) which comprises a pulse laser beam oscillator composed of a YAG laser oscillator or YVO4 laser oscillator and a repetition frequency setting means. A condenser 322 for converging a pulse laser beam oscillated from the pulse laser beam oscillation means is attached to the end of the above casing 321.

The image pick-up means 33 mounted on the end portion of the casing 321 constituting the above laser beam application means 32 comprises an infrared illuminating means for applying infrared radiation to the workpiece, an optical system for capturing infrared radiation applied by the infrared illuminating means, and an image pick-up device (infrared CCD) for outputting an electric signal corresponding to infrared radiation captured by the optical system, in addition to an ordinary image pick-up device (CCD) for picking up an image with visible radiation in the illustrated embodiment. An image signal is supplied to a control means that is not shown.

The laminate dividing step which is carried out by using the above laser beam processing machine 3 will be described with reference to FIGS. 3 to 5.

In this laminate dividing step, the semiconductor wafer 2 is first placed on the chuck table 31 of the laser beam processing machine 3 shown in FIG. 3 and suction-held on the chuck table 31. At this point, the semiconductor wafer 2 is held in such a manner that the front surface 2a faces up.

The chuck table 31 suction-holding the semiconductor wafer 2 is brought to a position right below the image pick-up means 33 by the moving mechanism that is not shown. After the chuck table 31 is positioned right below the image pick-up means 33, the image pick-up means 33 and the control means (not shown) carry out alignment work for detecting the area to be processed of the semiconductor wafer 2. That is, the image pick-up means 33 and the control means (not shown) carry out image processing such as pattern matching, etc. to align a street 23 formed in a predetermined direction of the semiconductor wafer 2 with the condenser 322 of the laser beam application means 32 for applying a laser beam along the street 23, thereby performing the alignment of a laser beam application position. The alignment of the laser beam application position is also carried out on streets 23 formed on the semiconductor wafer 2 in a direction perpendicular to the above predetermined direction.

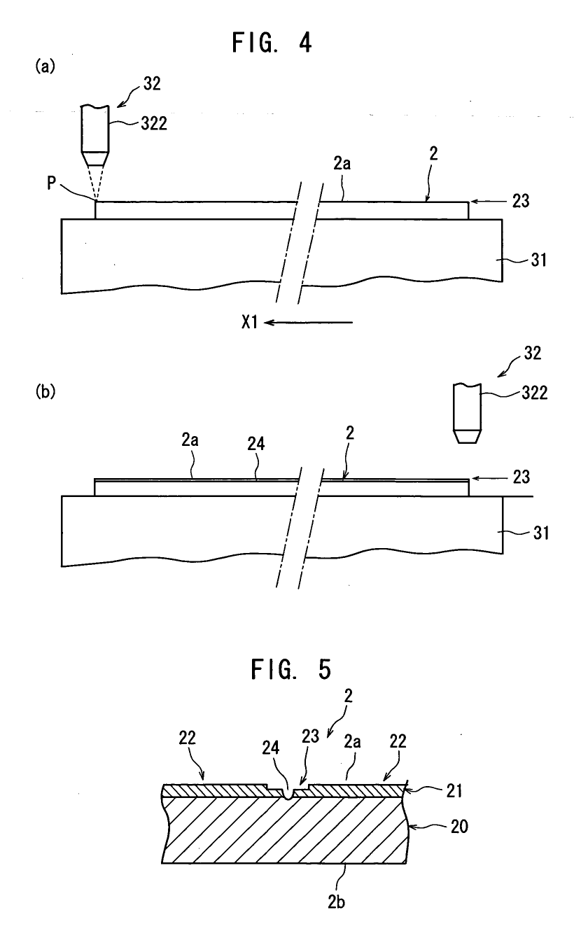

After the street 23 formed on the semiconductor wafer 2 held on the chuck table 31 is detected and the alignment of the laser beam application position is carried out as described above, the chuck table 31 is moved to a laser beam application area where the condenser 322 of the laser beam application means 32 for applying a laser beam is located as shown in FIG. 4(a) so as to bring the predetermined street 23 to a position right below the condenser 322. At this point, the semiconductor wafer 2 is positioned such that one end (left end in FIG. 4(a)) of the street 23 is located right below the condenser 322 as shown in FIG. 4(a). The chuck table 31, that is, the semiconductor wafer 2 is then moved in the direction indicated by the arrow X1 in FIG. 4(a) at a predetermined processing-feed rate while a pulse laser beam of a wavelength having absorptivity for the laminate 21 of the semiconductor wafer 2 is applied from the condenser 322 of the laser beam application means 32. When the other end (right end in FIG. 4(b)) of the street 23 reaches a position right below the condenser 322 as shown in FIG. 4(b), the application of the pulse laser beam is suspended and the movement of the chuck table 31, that is, the semiconductor wafer 2 is stopped. In this laminate dividing step, the focal point P of the pulse laser beam is set to a position near the front surface of the street 23.

By carrying out the above laminate dividing method, a laser-processed groove 24 deeper than the thickness of the laminate 21 is formed in the street 23 of the semiconductor wafer 2. As a result, the laminate 21 formed at the street 23 is divided along the street 21 by the laser-processed groove 24. The above laminate dividing method is carried out on all the streets 23 formed on the semiconductor wafer 2.

The above laminate dividing step is carried out under the following processing conditions, for example.

Light source of laser beam: LD excited Q switch Nd:YVO4 laser

Wavelength: 355 nm

Output: 0.5 to 2.5 W

Repetition frequency: 200 kHz

Pulse width: 200 ns

Focal spot diameter: 10 μm

Processing-feed rate: 300 to 500 mm/sec

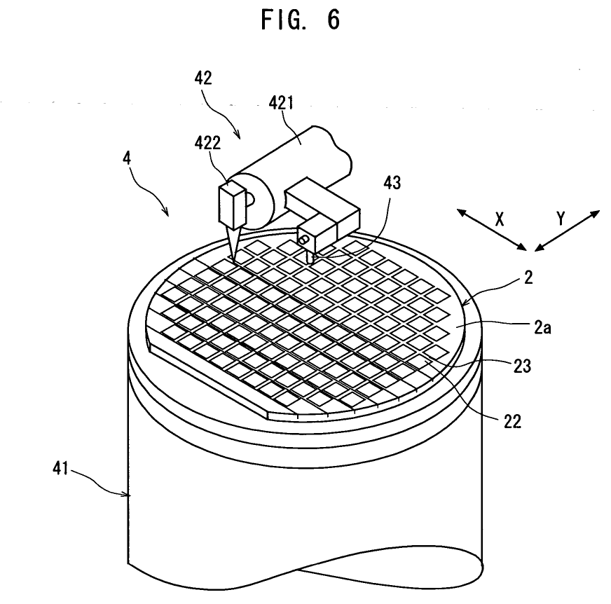

Another embodiment of the laminate dividing method will be described with reference to FIGS. 6 to 8.

The laminate dividing method of this embodiment is carried out by using an ultrasonic scribing apparatus 4 shown in FIG. 6. The ultrasonic scribing apparatus 4 shown in FIG. 6 comprises a chuck table 41 for holding a workpiece, an ultrasonic scribing unit 42 for carrying out the ultrasonic scribing-processing of the workpiece held on the chuck table 41, and an image pick-up means 43 for picking up an image of the workpiece held on the chuck table 41. The chuck table 41 is designed to suction-hold the workpiece and to be moved in the processing-feed direction indicated by the arrow X and the indexing-feed direction indicated by the arrow Y in FIG. 6 by a moving mechanism that is not shown.

The above ultrasonic scribing unit 42 has a cylindrical casing 421 arranged substantially horizontally. In the casing 421, there is installed an ultrasonic generating means that is not shown. An ultrasonic scriber 422 for applying an ultrasonic wave generated by the ultrasonic generating means to the workpiece is attached to the end of the above casing 421.

The image pick-up means 43 mounted on the end portion of the casing 421 constituting the above ultrasonic scribing unit 42 comprises an illuminating means for illuminating the workpiece, an optical system for capturing the area illuminated by the illuminating means and an image pick-up device (CCD) for picking up an image of the area captured by the optical system. An image signal is supplied to a control means that is not shown.

The laminate dividing step which is carried out by using the above ultrasonic scribing apparatus 4 will be described with reference to FIGS. 6 to 8.

In this laminate dividing step, the semiconductor wafer 2 is first placed on the chuck table 41 of the ultrasonic scribing apparatus 4 shown in FIG. 6 and suction-held on the chuck table 41. At this point, the semiconductor wafer 2 is held in such a manner that the front surface 2a faces up.

The chuck table 41 suction-holding the semiconductor wafer 2 as described above is brought to a position right below the image pick-up means 43 by the moving mechanism that is not shown. After the chuck table 41 is positioned right below the image pick-up means 43, the image pick-up means 43 and the control means (not shown) carry out alignment work for detecting the area to be scribed of the semiconductor wafer 2. That is, the image pick-up means 43 and the control means (not shown) carry out image processing such as pattern matching, etc. to align a street 23 formed in a predetermined direction of the semiconductor wafer 2 with the ultrasonic scriber 422 of the ultrasonic scribing unit 42 for scribing the semiconductor wafer 2 along the street 23, thereby performing the alignment of a scribing position. The alignment of the scribing position is also carried out on streets 23 formed on the semiconductor wafer 2 in a direction perpendicular to the above predetermined direction.

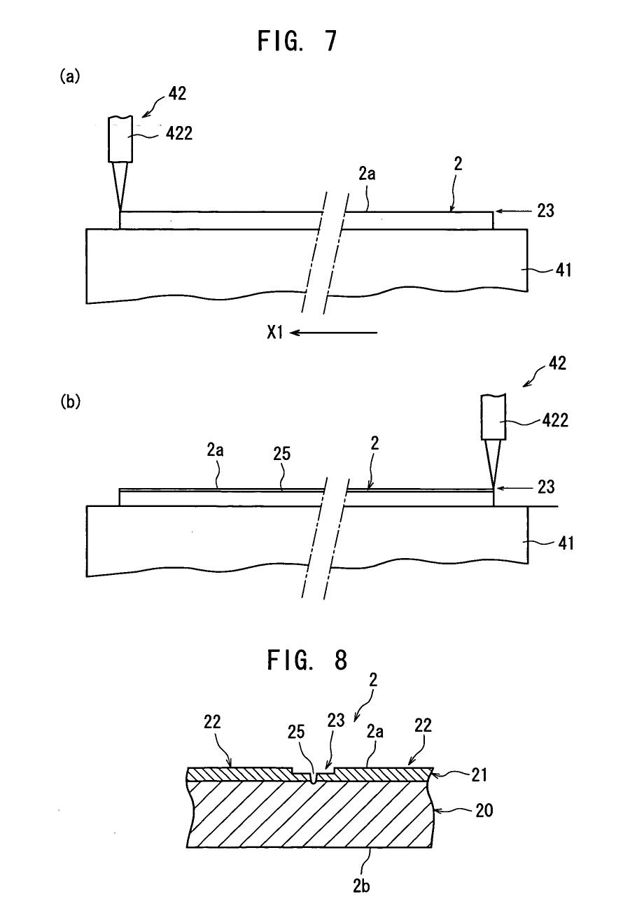

After the street 23 formed on the semiconductor wafer 2 held on the chuck table 41 is detected and the alignment of the scribing position is carried out as described above, the chuck table 41 is moved to a scribing area where the ultrasonic scriber 422 of the ultrasonic scribing unit 42 is located as shown in FIG. 7(a) so as to bring the predetermined street 23 to a position right below the ultrasonic scriber 422. At this point, the semiconductor wafer 2 is positioned such that one end (left end in FIG. 7(a)) of the street 23 is located right below the ultrasonic scriber 422. The ultrasonic scribing unit 42 is lowered to bring the ultrasonic scriber 422 into contact with the top surface of the street 23. The chuck table 41, that is, the semiconductor wafer 2 is then moved in the direction indicated by the arrow X1 in FIG. 7(a) at a predetermined processing-feed rate while the ultrasonic generating means (not shown) of the ultrasonic scribing unit 42 is turned on to exert ultrasonic vibration to the ultrasonic scriber 422. When the other end (right end in FIG. 7(b)) of the street 23 reaches a position right below the ultrasonic scriber 422 as shown in FIG. 7(b), the ultrasonic generating means (not shown) is turned off and the movement of the chuck table 41, that is, the semiconductor wafer 2 is stopped.

By carrying out the above laminate dividing step, the ultrasonic scriber 422 to which ultrasonic vibration is given is moved down (cutting-in fed) 2 to 5 μm, whereby a scribed groove 25 deeper than the thickness of the laminate 21 is formed in the street 23 of the semiconductor wafer 2, as shown in FIG. 8. As a result, the laminate formed at the street 23 is divided along the street 23 by the scribed groove 25. The above laminate dividing step is carried out on all the streets 23 formed on the semiconductor wafer 2.

The above laminate dividing step is carried out under the following processing conditions, for example.

Output: 20 to 100 W

Frequency: 40 kHz

Material of scriber: diamond

Processing-feed rate: 100 mm/sec

After the above laminate dividing step, next comes the step of forming a deteriorated layer in the inside of the semiconductor substrate 20 along the streets 23 by applying a laser beam having permeability for the semiconductor substrate 20 of the semiconductor wafer 2 from the rear surface 2a side of the semiconductor substrate 20 along the streets 23. This deteriorated layer forming step is carried out by using a laser beam processing machine constituted substantially the same as the laser beam processing machine shown in FIG. 3. The deteriorated layer forming step will be described by using the reference numerals of the laser beam processing machine 3 shown in FIG. 3. In the deteriorated layer forming step, the front surface 2a side of the semiconductor wafer 2 is placed on the chuck table 31 of the laser beam processing machine 3 shown in FIG. 3 (therefore, the rear surface 2b of the semiconductor wafer 2 faces up) and suction-held on the chuck table 31 by a suction means that is not shown. The chuck table 31 suction-holding the semiconductor wafer 2 is brought to a position right below the image pick-up means 33 by the moving mechanism that is not shown.

After the chuck table 31 is positioned right below the image pick-up means 33, the image pick-up means 33 and the control means (not shown) carry out alignment work for detecting the area to be processed of the semiconductor wafer 2. This alignment work is substantially the same as the alignment work in the laminate dividing step. Although the front surface 2a having the streets 23 formed thereon of the semiconductor wafer 2 faces down in this alignment work, as the image pick-up means 33 comprises an infrared illuminating means, an optical system for capturing infrared radiation and an image pick-up device (infrared CCD) for outputting an electric signal corresponding to the infrared radiation as described above, images of the streets 23 can be picked up through the rear surface 2b.

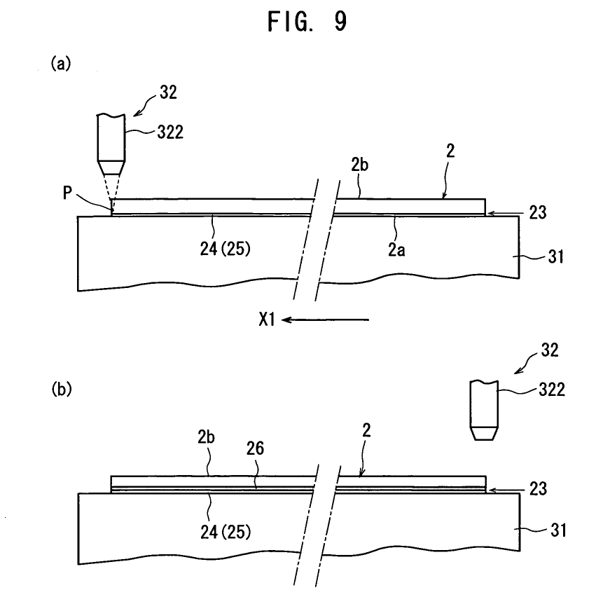

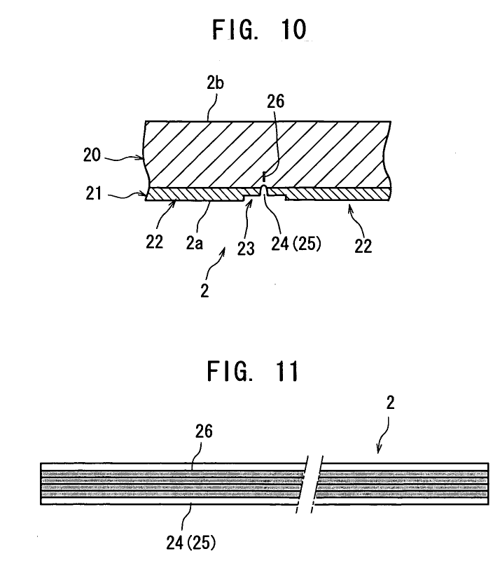

After the street 23 formed on the semiconductor wafer 2 held on the chuck table 31 is detected and the alignment of the laser beam application position is carried out as described above, the chuck table 31 is moved to a laser beam application area where the condenser 322 of the laser beam application means 32 for applying a laser beam is located as shown in FIG. 9(a) so as to bring one end (left end in FIG. 9(a)) of the predetermined street 23 to a position right below the condenser 322 of the laser beam application means 32. The chuck table 31, that is, the semiconductor wafer 2 is then moved in the direction indicated by the arrow X1 in FIG. 9(a) at a predetermined processing-feed rate while a pulse laser beam of a wavelength having permeability for the semiconductor substrate 20 is applied from the condenser 322. When the application position of the condenser 322 reaches the other end of the street 23 as shown in FIG. 9(b), the application of the pulse laser beam is suspended and the movement of the chuck table 31, that is, the semiconductor wafer 2 is stopped. In this deteriorated layer forming step, by setting the focal point P of the pulse laser beam to the inside of the semiconductor wafer 2, a deteriorated layer 26 is formed in the inside of the semiconductor wafer 2 along the street 23, as shown in FIG. 9(b) and FIG. 10. This deteriorated layer 26 is formed as a molten and re-solidified layer. The above deteriorated layer forming step is carried out on all the streets 23 formed on the semiconductor wafer 2.

The processing conditions in the above deteriorated layer forming step are set as follows, for example.

Light source: LD excited Q switch Nd:YVO4 laser

Wavelength: 1,064 nm

Output: 0.1 to 10 W

Repetition frequency: 100 kHz

Pulse width: 40 ns

Focal spot diameter: 1 μm

Processing-feed rate: 100 mm/sec

When the semiconductor wafer 2 is thick, the above-described deteriorated layer forming step is carried out several times by changing the focal point P stepwise so as to form a plurality of deteriorated layers 26 as shown in FIG. 11.

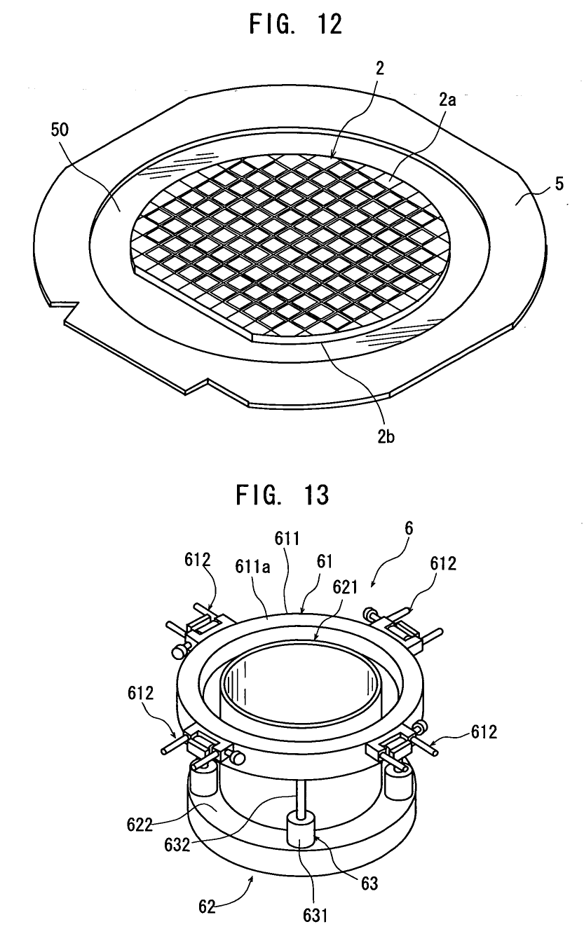

After the above deteriorated layer forming step, the rear surface 2b side of the semiconductor wafer 2 is put on the surface of an elastic support tape 50 which is composed of a synthetic resin sheet such as a polyolefin sheet and mounted on an annular frame 5, as shown in FIG. 12 (wafer supporting step). Therefore, the front surface 2a of the semiconductor wafer 2 faces up.

After the semiconductor wafer 2 is put on the surface of the support tape 50 mounted on the annular frame 5 as shown in FIG. 12, next comes the step of dividing the semiconductor wafer 2 along the streets 23 by exerting external force to the semiconductor wafer 2 where the deteriorated layers 26 have been formed. In the illustrated embodiment, this wafer dividing step is carried out by using a dividing apparatus 6 shown in FIG. 13. The dividing apparatus 6 shown in FIG. 13 comprises a frame holding means 61 for holding the above annular frame 5 and a tape expanding means 62 for expanding the support tape 50 mounted on the annular frame 5 held on the frame holding means 61. The frame holding means 61 comprises an annular frame holding member 611 and a plurality of clamps 612 as a fixing means arranged around the frame holding member 611. The top surface of the frame holding member 611 serves as a placing surface 611a for placing the annular frame 5, and the annular frame 5 is placed on the placing surface 611a. The annular frame 5 placed on the placing surface 611a is fixed on the frame holding member 611 by the clamps 612. The frame holding means 61 constituted as described above is supported by the tape expanding means 62 in such a manner that it can move in the vertical direction.

The tape expanding means 62 comprises an expansion drum 621 arranged within the above annular frame holding member 611. This expansion drum 621 has a smaller outer diameter than the inner diameter of the annular frame 5 and a larger inner diameter than the outer diameter of the semiconductor wafer 2 affixed to the support tape 50, mounted on the annular frame 5. The expansion drum 621 has a support flange 622 at the lower end. The tape expanding means 62 in the illustrated embodiment has a support means 63 which can move the above annular frame holding member 611 in the vertical direction. This support means 63 are composed of a plurality of air cylinders 631 installed on the above support flange 622, and their piston rods 632 are connected to the undersurface of the above annular frame holding member 611. The support means 63 composed of the plurality of air cylinders 631 moves the annular frame holding member 611 in the vertical direction between a standard position where the placing surface 611a becomes substantially flush with the upper end of the expansion drum 621 and an expansion position where the placing surface 611a is positioned below the upper end of the expansion drum 621 by a predetermined distance. Therefore, the support means 63 comprising the plurality of air cylinders 631 functions as an expanding and moving means for moving the frame holding member 611 relative to the expansion drum 621 in the vertical direction.

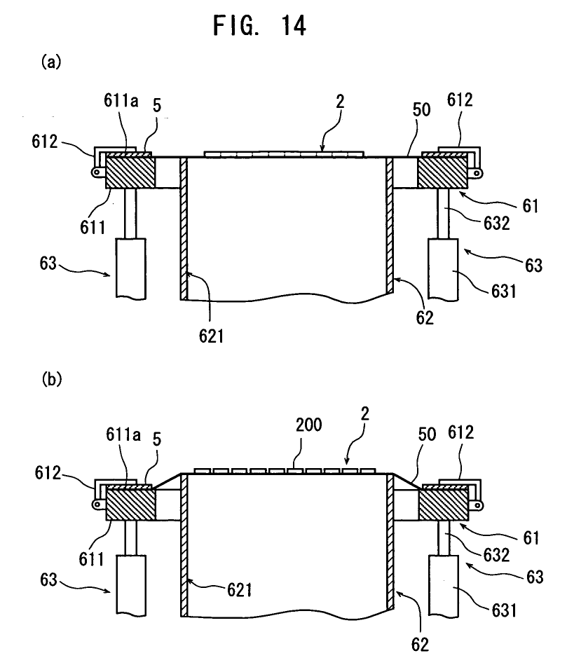

The dividing step which is carried out by using the dividing apparatus 6 constituted as described above will be described with reference to FIGS. 14(a) and 14(b). That is, the annular frame 5 supporting the semiconductor wafer 2 (the laser-processed groove 24 or the scribed groove 25 and the deteriorated layer 26 are formed along the streets 23) through the support tape 50 is placed on the placing surface 611a of the frame holding member 611 constituting the frame holding means 61, and fixed on the frame holding member 611 by the clamps 612, as shown in FIG. 14(a). At this moment, the frame holding member 611 is situated at the standard position shown in FIG. 14(a). The annular frame holding member 611 is lowered to the expansion position shown in FIG. 14(b) by activating the plurality of air cylinders 631 as the support means 63 constituting the tape expanding means 62. Therefore, the annular frame 5 fixed on the placing surface 611a of the frame holding member 611 is also lowered, whereby the support tape 50 mounted on the annular frame 5 comes into contact with the upper edge of the expansion drum 621 to be expanded as shown in FIG. 14(b) (tape expanding step). As a result, tensile force acts radially on the semiconductor wafer 2 affixed to the support tape 50. When tensile force thus acts radially on the semiconductor wafer 2, the semiconductor wafer 2 is divided into individual semiconductor chips 200 along the deteriorated layers 26 as dividing start points because the deteriorated layers 26 formed along the streets 21 have reduced strength. Since the laser-processed groove 24 or the scribed groove 25 deeper than the thickness of the laminate 21 is formed in the streets 23 of the semiconductor wafer 2 as shown in FIG. 5 or FIG. 8 and the laminate 21 is divided along the streets 23, the semiconductor wafer 2 is divided along the streets 23 without fail. Further, since the laminate 21 is divided along the streets 23 by the laser-processed grooves 24 or the scribed grooves 25, it does not peel off when the semiconductor wafer 2 is divided along the streets 23, thereby making it possible to overcome a problem such as the reduction of the qualities of the semiconductor chips 200 by the peeling of the laminate 21.

The following dividing methods may be employed besides the above dividing method.

That is, a method in which the semiconductor wafer 2 put on the support tape 50 (the laser-processed groove 24 or the scribed groove 25 and the deteriorated layer 26 are formed along the streets 23) is placed on a soft rubber sheet and the top surface of the semiconductor wafer 2 is pressed with a roller to divide the semiconductor wafer 2 along the streets 21 whose strength has been reduced by the formation of the deteriorated layers 26 may be employed. Alternatively, a method in which an ultrasonic wave such as a longitudinal wave (compressional wave) having a frequency of about 28 kHz is applied along the streets 21 whose strength has been reduced by the formation of the deteriorated layers 26 may be employed.

A second embodiment of the method of dividing the above semiconductor wafer 2 along the streets 23 will be described hereinunder.

In the second embodiment, the step of forming a deteriorated layer in the inside of the semiconductor substrate 20 along the streets 23 by applying a laser beam having permeability for the semiconductor substrate 20 of the semiconductor wafer 2 from the rear surface 2b side of the semiconductor substrate 20 along the streets 23 is first carried out. This deteriorated layer forming step can be carried out in the same manner as the deteriorated layer forming step which is shown in FIGS. 9 to 11 by using a laser beam processing machine which is constituted substantially the same as the laser beam processing machine 3 shown in FIG. 3. At this point, the laser-processed groove 24 or the scribed groove 25 is not formed along the streets 23 in the semiconductor wafer 2.

After the above deteriorated forming step, next comes the step of putting the rear surface 2b side of the semiconductor wafer 2 on the surface of the support tape 50 mounted on the annular frame 5 shown in FIG. 12. Therefore, the front surface 2a of the semiconductor wafer 2 faces up. At this point, the laser-processed groove 24 or the scribed groove 25 is not formed along the streets 23 in the semiconductor wafer 2.

The wafer supporting step is followed by the step of dividing the laminate 21 laminated at the streets 23 of the semiconductor wafer 2 along the streets 23. This laminate dividing step is carried out by using the laser beam processing machine 3 shown in FIG. 3 or the ultrasonic scribing apparatus 4 shown in FIG. 6. When the laser beam processing machine 3 is used, the laminate dividing step is carried out in the same manner as the laminate dividing step shown in FIGS. 4(a) and 4(b) and FIG. 5. When the ultrasonic scribing apparatus 4 is used, the laminate dividing step is carried out in the same manner as the laminate dividing step shown in FIGS. 7(a) and 7(b) and FIG. 8. In the laminate dividing step, the semiconductor wafer 2 is held on the chuck table 31 of the laser beam processing machine 3 or the chuck table 41 of the ultrasonic scribing apparatus 4 through the support tape 50.

After the above laminate dividing step, next comes the step of dividing the semiconductor wafer 2 along the streets 23 by exerting external force to the semiconductor wafer 2 where the deteriorated layers 26 have been formed. This dividing step is carried out by using the dividing apparatus 6 shown in FIG. 13 as shown in FIGS. 14(a) and 14(b).

What is claimed is:

1. A method of dividing a wafer having devices which are composed of a laminate formed on the front surface of a substrate, along a plurality of streets sectioning the devices, comprising:
a laminate dividing step for dividing the laminate formed at the streets of the wafer along the streets;
a deteriorated layer forming step for forming a deteriorated layer in the inside of the substrate along the streets by applying a laser beam of a wavelength having permeability for the substrate of the wafer from the rear surface of the wafer along the streets; and
a dividing step for dividing the wafer along the streets by exerting external force to the wafer where the deteriorated layers have been formed.

2. The wafer dividing method according to claim 1, wherein the laminate dividing step is to form a laser-processed groove deeper than the thickness of the laminate by applying a laser beam of a wavelength having absorptivity for the laminate from the front surface side of the wafer along the streets formed on the wafer.

3. The wafer dividing method according to claim 1, wherein the laminate dividing step is to form a scribed groove deeper than the thickness of the laminate by scribing along the streets formed on the wafer.
